(19) United States
(12) Patent Application Publication
(10) Pub. No.: US 2005/0109459 A1
(43) Pub. Date: May 26, 2005

(54) High density plasma apparatus and methods of operating the same

(76) Inventor: Young-Min Kwon, Incheon-city (KR)

Correspondence Address: GROSSMAN & FLIGHT LLC;Suite 4220, 20 North Wacker Drive, Chicago, IL, 60606-6357, US

(21) Appl. No.: 10/960,556

(22) Filed: Oct. 6, 2004

(30) Foreign Application Priority Data
Oct. 6, 2003 (KR) 10-2003-0069185

(51) Int. Cl. C23F 1/00; H01L 21/306

(52) U.S. Cl. 156/345.32

(57) ABSTRACT

Disclosed is a high density plasma apparatus, which is capable of preventing breakage of an insulation film due to a potential difference by removing the potential difference in the course of transferring a wafer from a process chamber to a transfer chamber after completing a plasma process. The high density plasma apparatus may include a transfer chamber including a wafer transfer robot; a process chamber connected to the transfer chamber for plasma-processing a wafer being transferred by the wafer transfer robot; and an ultraviolet irradiator provided in the transfer chamber for irradiating an ultraviolet ray on the wafer plasma-processed in the process chamber and being transferred to the transfer chamber.

### TECHNICAL FIELD

The present disclosure relates to plasma apparatus and, more particularly, to high density plasma apparatus and methods of operating the same.

### BACKGROUND

Generally, a process for producing semiconductor products includes producing a wafer, forming a semiconductor chip by forming a semiconductor thin film on the wafer, and a packaging step of separating the semiconductor chip from the wafer. Semiconductor production further includes electrically connecting the semiconductor chip to an external device, protecting the semiconductor chip from poor external environments, and a test step.

Also, the step of forming a semiconductor chip includes a preceding semiconductor thin film forming sub-step of applying and patterning a photoresist on the wafer, and a subsequent semiconductor thin film forming sub-step of performing deposition, etch, and ion implantation on other thin film material via the patterned photoresist.

Recently, as one example of semiconductor fabrication devices used for the subsequent semiconductor thin film forming sub-step, a high density plasma apparatus for depositing material without leaving any voids in contact holes having high aspect ratio has been developed and used. Such a high density plasma apparatus includes a central transfer chamber having a transfer robot, and a plurality of process chambers connected around the transfer chamber. The transfer robot loads a wafer into a wafer mounting chuck provided in each process chamber. Under this condition, a reactive gas and/or a source gas are supplied into the process chamber to generate plasma for depositing deposition material on the wafer, which is then etched by the plasma. These processes, as mentioned above, are repeated to form an insulation film having an extremely compactly structure on the wafer.

After the insulation film forming process by the high density plasma apparatus is completed, a slit provided between the process chamber and the transfer chamber is opened and the wafer is transferred to the transfer chamber by the transfer robot for a subsequent process. However, the high density plasma apparatus has a problem in that the insulation film may be impaired by plasma charging.

The reason for the impairment of the insulation film is as follows. The wafer is transferred to the transfer chamber through the slit between the transfer chamber and the process chamber with the wafer placed on a blade of the transfer robot. At this time, the process chamber is exposed to residual plasma and the transfer chamber is not affected by the plasma. In this condition, because the insulation film was formed on a surface of the wafer, a difference in potential occurs between a portion exposed to the plasma and a portion not exposed to the plasma, which may result in an impairment such as a semicircle of the insulation film. Techniques for overcoming this problem are disclosed in U.S. Pat. Nos. 6,190,518, 6,309,979, 6,423,653, and 6,638,833.

### BRIEF DESCRIPTION OF THE DRAWINGS

FIG. 1 is a schematic plan view illustrating a high density plasma apparatus according to one disclosed example.

FIG. 2 is a schematic side sectional view illustrating a main portion of FIG. 1.

### DETAILED DESCRIPTION

Disclosed herein is an apparatus for forming a compact deposition film by performing a deposition process and an etching process on a wafer simultaneously using a plasma gas in a semiconductor fabrication process. More specifically, disclosed herein is a high density plasma apparatus that is capable of preventing a damage of the wafer due to the plasma gas in the course of moving the wafer to a transfer chamber in a process chamber.

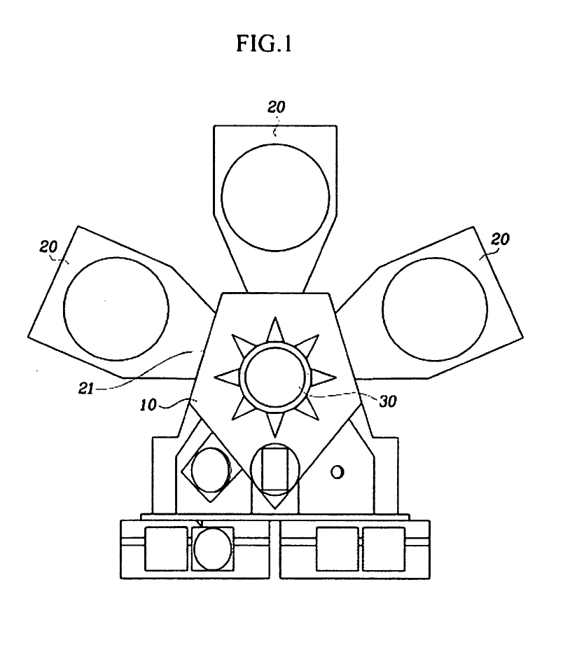

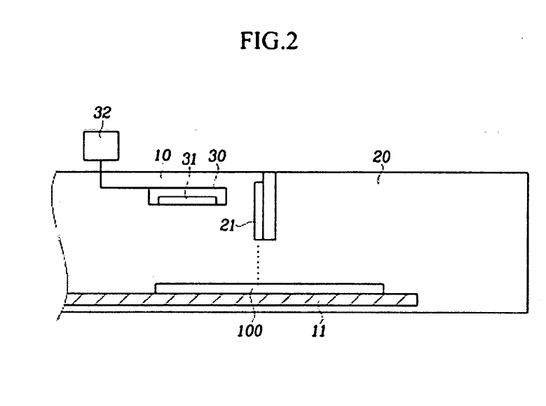

FIG. 1 is a schematic plan view illustrating a high density plasma apparatus according to an embodiment of the present invention. FIG. 2 is a schematic side sectional view illustrating a main portion of FIG. 1.

The high density plasma apparatus comprises a transfer chamber 10 incorporating a transfer robot for transferring a wafer 100 to be processed, and a plurality of process chambers 20 arranged around the transfer chamber 10 for forming an insulation film.

Although not shown in the drawings, each of the process chambers 20 includes a wafer mounting chuck on which the wafer 100 is mounted, a reactive gas/source gas supplier for introducing reactive gas/source gas into the process chamber 20, and a plasma generator for converting the source gas into plasma.

With the high density plasma apparatus as constructed above, a plasma process is performed when the wafer 100 transferred to the transfer chamber 10 is mounted on the wafer mounting chuck after the wafer 100 is introduced into the process chamber 20 through a slit 21 provided between the transfer chamber 10 and the process chamber 20 with the wafer 100 placed on a blade 11 of the transfer robot. After the plasma process is completed, the wafer 100 is again transferred to the transfer chamber 10 for a subsequent process.

The high density plasma apparatus further comprises an ultraviolet ray irradiator for irradiating an ultraviolet ray on the wafer 100 being transferred from the process chamber 20 to the transfer chamber 10.

The ultraviolet ray irradiator comprises a source of light 31 provided in the transfer chamber via a bracket 30 for irradiating the ultraviolet ray, and a power supplier 32 for supplying a power to the source of light 31.

As the source of light 31, a mercury lamp may be used. Alternatively, a mercury arc lamp, a carbon arc lamp, a hydrogen discharge tube, a helium discharge tube, a Lyman discharge tube, etc. may be used as the source of light 31.

Now, operation and effect of the high density plasma apparatus as constructed above will be described. The wafer 100, which was subject to a preceding process, is transferred to the transfer chamber 10 of the high density plasma apparatus, and then transferred to the process chamber 20 through the slit 21 by the transfer robot of the transfer chamber 10.

When the transfer robot is withdrawn after the wafer 100 transferred to the process chamber 20 is mounted on the wafer mounting chuck, the slit 21 is shut to seal up the process chamber 20. Thereafter, when a constant electric field is generated in the wafer by means of the plasma generator, the reactive gas or source gas is introduced into the process chamber 20 by means of the reactive gas/source gas supplier according to a process sequence.

Then, the source gas introduced into the process chamber 20 is changed into plasma by the electric field generated by the plasma generator and the internal temperature of the process chamber 20 rises rapidly by the plasma. Subsequently, when the reactive gas chemically reacts with the plasma to generate deposition material according to the rising of the internal temperature of the process chamber 20, this deposition material begins to be deposited on the top surface of the wafer 100. The deposition material deposited on the wafer 100 is etched by the plasma. The procedures as described above are repeated to form an extremely compact insulation film on the wafer 100.

After the plasma process is terminated, the slit is opened and the wafer 100 on which the insulation film is formed is transferred to the transfer chamber 10 by the blade 11 of the transfer robot. At this time, in the course of transferring the wafer 100 from the process chamber 20 to the transfer chamber 10 after terminating the plasma process, the mercury lamp being the source of light 31 provided in the transfer chamber 10 is turned on to irradiate the ultraviolet ray on the wafer 100 being transferred to the transfer chamber 10.

Accordingly, an exposure unbalance may be alleviated by the residual plasma in the process chamber 20 and the ultraviolet ray in the transfer chamber 10. More specifically, because the plasma remains in the process chamber 20 after terminating the plasma process, one portion of the wafer 100 located in the process chamber 20 is exposed to the remaining plasma in the course of transferring the wafer 100 from the process chamber 20 to the transfer chamber 10. At this time, because the mercury lamp irradiates the ultraviolet ray on other portions of the wafer 100 come out of the process chamber 20 and located in the transfer chamber 10, the exposure unbalance can be alleviated over the whole of the wafer 100.

As disclosed herein, a high density plasma apparatus is capable of preventing breakage of an insulation film due to a potential difference by removing the potential difference in the course of transferring a wafer from a process chamber to a transfer chamber after completing a plasma process. According to this disclosure, the potential difference occurring in the wafer due to residual plasma within the process chamber is removed. The high density plasma apparatus may include an ultraviolet ray irradiator for irradiating an ultraviolet ray on a wafer being transferred from a process chamber to the transfer chamber.

Plasma damage due to the potential difference can be prevented because a potential difference for each region of the wafer located within the process chamber and the transfer chamber can be removed,

As is apparent from the above description, with the high density plasma apparatus disclosed herein, the potential difference in the wafer due to an unbalanced plasma exposure can be prevented, and accordingly, plasma damage such as breakage of an insulation film can be prevented.

This patent application makes reference to, incorporates the same herein, and claims all benefits accruing under 35 U.S.C. §119 from an application for HIGH DENSITY PLASMA APPARATUS filed in the Korean Industrial Property Office on Oct. 06, 2003 and there duly assigned Serial No. 10-2003-0069185.

Although the preferred embodiment of the present invention has been described in detail hereinabove, it should be clearly understood that many variations and/or modifications of the basic inventive concepts herein taught which may appear to those skilled in the present art will still fall within the spirit and scope of the present invention, as defined in the appended claims.

1. A high density plasma apparatus comprising:
a transfer chamber having a wafer transfer robot;
a process chamber connected to the transfer chamber to plasma-process a wafer being transferred by the wafer transfer robot; and
an ultraviolet irradiator to irradiate an ultraviolet ray on the wafer plasma-processed in the process chamber and being transferred to the transfer chamber.

2. The high density plasma apparatus of claim 1, wherein the ultraviolet irradiator is provided in the transfer chamber.

3. The high density plasma apparatus of claim 1, wherein the ultraviolet irradiator is provided in the process chamber.

4. The high density plasma apparatus of claim 1 more comprises a slit provided between the transfer chamber and the process chamber.

5. The high density plasma apparatus of claim 1, wherein the ultraviolet irradiator is provided in the slit.

6. The high density plasma apparatus of claim 1, wherein the ultraviolet irradiator comprises a source of light to irradiate the ultraviolet, a bracket to dispose the source of light and a power supplier to supplying a power to the source of light.

7. The high density plasma apparatus of claim 6, wherein the source of light comprises a mercury lamp, a mercury arc lamp, a carbon arc lamp, a hydrogen discharge tube, a helium discharge tube, or a Lyman discharge tube.

8. The method of operating a high density plasma apparatus comprising:
transferring a wafer from a transfer chamber to a process chamber by a transfer robot;
performing high density plasma process on the wafer in the process chamber;
transferring the wafer plasma-processed in the process chamber to the transfer chamber; and
irradiating an ultraviolet ray on the wafer being transferred from the process chamber to the transfer chamber.

9. The method of claim 8, wherein the irradiating the ultraviolet ray is performed in the transfer chamber or the process chamber.

10. The method of claim 8, wherein the irradiating the ultraviolet ray is perform in a silt provided between transfer chamber and the process chamber.

11. The method of claim 8, wherein the irradiating the ultraviolet ray is performed by a mercury lamp, a mercury arc lamp, a carbon arc lamp, a hydrogen discharge tube, a helium discharge tube, or a Lyman discharge tube.
